(19) United States
(12) Patent Application Publication
(10) Pub. No.: US 2026/0238182 A1
(43) Pub. Date: Aug. 13, 2026

(54) Piezoelectric Resonator

(71) Applicant: COMMISSARIAT A L'ENERGIE ATOMIQUE ET AUX ENERGIES ALTERNATIVES, PARIS (FR)

(72) Inventors: Ghislain DESPESSE, GRENOBLE (FR); Alexandre REINHARDT, GRENOBLE (FR)

(21) Appl. No.: 19/426,767

(22) Filed: Dec. 19, 2025

(30) Foreign Application Priority Data
Dec. 20, 2024 (FR) 2414947

(51) Int. Cl. H03H 9/13; H03H 9/17

(52) U.S. Cl. CPC H03H 9/132; H03H 9/176

(57) ABSTRACT

The invention relates to a piezoelectric resonator, notably for a power converter, comprising:
a piezoelectric layer;
two conductive electrodes extending on either side of the piezoelectric layer so that the piezoelectric layer is sandwiched between the two conductive electrodes, with each conductive electrode being laterally delimited by a frame having a thickness different from that of the corresponding electrode; the frames of the two electrodes being substantially symmetrical with respect to each other relative to a median plane M extending through the middle of the thickness e_{piezo} of the piezoelectric layer.

The present invention relates to piezoelectric resonators, notably for power converters, with the power converters comprising such resonators, and to a method for using such resonators in power converters.

### TECHNICAL FIELD

Power converters are now ubiquitous in our daily lives, enabling all our electronic devices to be powered, whether or not they are mobile. As they are necessary for all our electronic devices, attempts are made to make them smaller, less loss generating and more efficient.

One of the proposed solutions involves increasing their operating frequency in order to reduce the volume of any transient energy storage components (i.e., passive components). However, there are still limits to this increase in frequency. These are notably found in magnetic storage components, which have intrinsic iron losses and are subject to the skin effect, with the two phenomena worsening as the frequency increases. This hinders improvements in the efficiency of power converters.

In order to address this problem, the use of piezoelectric resonators has been proposed. These resonators are notably used between their resonant and anti-resonant frequencies on a normal mode of the structure (for example, radial, longitudinal, thickness, shear, etc.). Between these two frequencies, they have features that are similar to those of the magnetic inductors that are intended to be replaced. The resonant modes that are used are of the mechanical type. Thus, the mechanical structure of the resonator must be taken into account, as it can be the source of wave leakages outside the resonator (therefore of losses), but can also include unwanted resonant modes that can interfere with the system in its working/operating frequency band.

Therefore, finding a resonator structure with a main resonant mode with a high electromechanical coupling coefficient is crucial for promoting the energy exchange between the resonator and the surrounding electrical circuit, and with a high quality factor and the minimum number of parasitic modes or the least possible coupled parasitic modes in the working frequency band. Furthermore, the acoustic wave must remain confined within the resonator and propagate as little as possible to the outside.

Piezoelectric resonators are used in many fields, notably for acoustic filters, notably for radio frequencies, as well as volume wave resonators, notably those using materials such as quartz acting as a time base (atomic clocks). The prior art in the field of piezoelectric resonators has been significantly influenced by previous work in these fields. Solutions have been proposed in the radio frequency field. Examples include those described in the work by J. Kaitila entitled, “3C-1 Review of Wave Propagation in BAW Thin Film Devices—Progress and Prospects”, 2007 IEEE Ultrasonics Symposium Proceedings, New York, NY, USA, 2007, pp. 120-129, doi: 10.1109/ULTSYM.2007. 43, which focuses on the use of structures comprising a piezoelectric substrate covered on one side by an electrode with a constant thickness extending over its entire length, and on the other side by an electrode with a reduced extent covering only the active part of the resonator and having a thickened edge (called frame or border-ring). Kaitila notably explains that the inertia provided by the electrode in the active area allows the resonant frequency of the resonator in this area to be lowered relative to the frequency of the same vibration mode outside the active area, which allows the vibration mode to be confined within the limits of the active area. The purpose of the thickened frame is to facilitate the establishment of a resonant mode with uniform amplitude throughout the area inside this frame by facilitating the transition between the internal active area of the resonator and the external area. Outside the resonator, the vibration is not completely zero, but is drastically attenuated, limiting the propagation of waves to the outside and therefore the associated energy loss and the risks of reflection of these waves and the associated parasitic resonances. This frame, which is only present on one side, also introduces mechanical constraints and manufacturing challenges, notably due to differences in thermal expansion coefficients between the materials. In addition, energy is converted to unwanted modes due to the presence of the thickened frames on only one side, thus resulting in the problem of additional parasitic modes, notably of higher-order shear or longitudinal modes.

As an alternative to the thickened frame, thinned frames are also known from the article by R. Thalhammer and J. D. Larson entitled, “Finite element analysis of BAW devices: Principles and perspectives”, in Proceedings of the 2015 IEEE International Ultrasonics Symposium. The analysis and the issues are similar to those above in the case of the thickened frame.

The article by T. Wu, H-y Luo, Y.-w Feng, J.-f Bao and K.-y Hashimoto entitled, “Ultra-wideband longitudinally coupled-resonator filters on lithium niobate using periodically slotted SiO₂ as an acoustic coupler”, in the Japanese Journal of Applied Physics, volume 63, 02SP87 (2024), also describes, as an alternative to the resonators described in the aforementioned work by Kaitila, two resonator structures coupled to each other by an intermediate structure and with separate electrical excitation for the two resonator structures. One of the two resonator structures is similar to the structure described by Kaitila in the aforementioned article and the other has, on either side of the piezoelectric substrate, electrodes extending over the entire surface of the substrate, with the electrode opposite the other resonator structure having the same over-thicknesses as the frames of the other resonator structure. Such a resonator has symmetrical over-thicknesses on either side of the structure, which reduces the presence of additional parasitic modes due to the frames and avoids thick material deposits by distributing the over-thickness on either side of the resonator. Nevertheless, the structure is complex due to the need for two resonator structures with separate electrical excitations.

These solutions have been developed for the radio frequency field, where the issue of frame thickness remains minor due to the small dimensions of the resonators. The field of power converters requires piezoelectric layer thicknesses that are greater than those used in radio frequency filters, by a factor of 100 to 1,000, in line with the ratio of the operating frequencies of the components. As the over-thickness of the frame is substantially proportional to the thickness of the piezoelectric layer, homothetic dimensioning of the frames is necessary, which makes the issue of thick material deposits more significant and problematic than in the radio frequency field. Therefore, it would appear that some of the issues described above are more or less significant depending on the specifics of the technical fields in which piezoelectric resonators are used.

Another solution proposed by E. Stolt et al., in the article entitled, “A Spurious-Free Piezoelectric Resonator Based 3.2 kW DC-DC Converter for EV On-Board Chargers”, in IEEE Transactions on Power Electronics, volume 39, number 2, pp. 2478-2488 February 2024, doi: 10.1109/TPEL.2023.3334211, involves the use of short-circuit rings around the resonators on one side. Although this method can reduce energy losses in a similar way to the thickened frame, it limits the voltage that can be applied on the resonator terminals to the breakdown voltage in the vicinity of the one or more air gaps between the ring and the resonator electrode. However, this air gap must be small relative to the thickness in order for the ring to completely fulfil its role (in this case 120 μm for a thickness of 500 μm). Therefore, the electrical performance is even more limited. In addition, an electrical connection needs to be added between the upper and the lower electrode of the ring, which adds a manufacturing constraint. Furthermore, as the difference in mechanical impedance between the resonator area and the ring area is low, the required ring width is quite large in order to achieve an effect similar to that of the previous frame with an over-thickness. The ring therefore occupies a significant area relative to that of the resonator, equally reducing the achievable power density and increasing the lateral footprint of the resonator. Finally, the difference in the impedance of the piezoelectric structure between the resonator area and the ring area is imposed solely by the effect of the electrical short circuit, so there is no degree of freedom for optimally selecting this impedance, notably with regard to the occupied surface area or the parasitic modes.

In brief, despite the progress that has been made, current piezoelectric resonators still suffer from limitations in terms of performance, efficiency and compactness.

Notably, a requirement exists to further minimize the deformation energy transmitted outside the piezoelectric resonator and to promote energy transfer inside the resonator on a single resonant mode, while reducing the parasitic modes and limiting the overall size of the system, which is important for reducing the volume of the power converters in particular.

Therefore, a requirement exists for efficient, easy-to-manufacture and compact piezoelectric resonators, notably in the case of power converters.

### SUMMARY OF THE INVENTION

The invention addresses this requirement, notably by means of a piezoelectric resonator comprising:
a piezoelectric layer;
two conductive electrodes extending on either side of the piezoelectric layer so that the piezoelectric layer is sandwiched between the two conductive electrodes, with each conductive electrode being laterally delimited by a frame having a thickness different from that of the corresponding electrode;
the frames of the two electrodes being substantially symmetrical with respect to each other relative to a median plane extending through the middle of the thickness of the piezoelectric layer.

“Substantially symmetrical” is understood to mean symmetrical with respect to each other with tolerances, notably manufacturing tolerances, in terms of dimensions, notably thicknesses and/or width, and/or mutual alignment. The symmetry is notably to the nearest 10%, preferably to the nearest 5%, more preferably to the nearest 2%. The thickness and the width of the two frames can be identical to the nearest 10%, preferably to the nearest 5%, more preferably to the nearest 2%. The frames can be symmetrically aligned with each other with respect to the median plane to the nearest 10%, preferably to the nearest 5%, more preferably to the nearest 2%. In order to maintain the symmetry, the two frames are ideally made of identical materials.

“Laterally delimited” is understood to mean that the electrode is confined or limited on the edges thereof by a nearby frame. This frame is preferably in contact with the edge of the electrode or superposes it, thus forming a lateral frame that determines the extent of the active surface of the electrode. A proximity tolerance can be allowed, allowing the frame to be located at a distance from the edge of the electrode, while maintaining the integrity of the lateral delimitation according to the specifications of the device.

The lack of space between the electrode and the frame prevents an additional mechanical impedance discontinuity that would be associated with an intermediate space. By thus limiting any impedance discontinuities, the risks of energy transfer to unwanted resonance modes is reduced.

The resonator thus comprises:
a work area defined by the superposing area of the piezoelectric layer and of the electrodes;
a frame area defined by the superposing area of the piezoelectric layer and of the frames and having a thickness different from that of the work area;
and
an external area defined outside the other two areas.

This configuration offers numerous technical advantages.

Notably, such a resonator allows the acoustic waves to be confined within the work area. The symmetry of the electrode frames confines the waves inside the work area, thereby reducing energy losses due to the propagation of waves to the outside, notably to the external area. This improves the overall efficiency of the resonator.

By laterally delimiting the electrodes with substantially symmetrical frames, the invention minimizes the excitation of parasitic resonant modes. This allows a purer signal to be obtained and reduces any unwanted interference, which is crucial for high-precision applications.

The sandwich configuration whereby the piezoelectric layer is sandwiched between two conductive electrodes, with substantially symmetrical frames, promotes a piston mode inside the work area. This means that the deformation is substantially synchronous and has a substantially homogeneous amplitude, which improves the electromechanical coupling and the energy conversion efficiency.

Having frames on both sides notably facilitates manufacturing by reducing the difference in the required thickness compared to the case of a frame on only one electrode. Indeed, the difference in thickness is then distributed over both sides, thus reducing the thickness of each frame.

In summary, the invention proposes an innovative technical solution for improving the performance capabilities of piezoelectric resonators in terms of wave confinement, reduction of parasitic modes, electromechanical coupling and ease of manufacturing. These advantages make the invention particularly suitable for applications requiring compact and efficient devices, such as power converters and other advanced electronic systems.

Preferably, the piezoelectric resonator is for a power converter.

### Symmetry

Preferably, the thickness of the external area, notably of the piezoelectric layer, is less than that of the resonator area and of the frame area.

The electrodes can be substantially symmetrical with respect to each other relative to the median plane extending through the middle of the thickness of the piezoelectric layer.

Preferably, the external area and/or the work area are substantially symmetrical relative to the median plane extending through the middle of the thickness of the piezoelectric layer.

The resonator can be substantially symmetrical relative to the median plane extending through the middle of the thickness of the piezoelectric layer. This symmetry notably allows the mechanical stresses and the distortions at the interface to be avoided, which improves the stability and the performance of the resonator.

The resonator also can be substantially symmetrical relative to a transverse plane extending perpendicular to the median plane. This allows the parasitic resonant modes to be reduced that can interfere with the operation of the resonator. Indeed, a structure that is symmetrical relative to the transverse plane prevents the excitation of odd modes (n=1, 3, etc.) due to the compensation of electrical charges over the entire surface of the electrodes. The symmetry relative to the median plane reduces the excitation of the even modes (n=2, 4, etc.). In addition, the presence of frames also reduces the excitation of these even modes. Secondly, the frames help to maintain a homogeneous deformation inside the resonator, which promotes high electromechanical coupling and limits the propagation of waves to the outside, thus reducing energy losses. These features are particularly advantageous for the performance and the efficiency of piezoelectric resonators in power conversion applications.

### Piezoelectric Layer

Preferably, the piezoelectric layer is a single layer. It can be made of a single material over its entire surface area and a single layer over its thickness. This notably avoids having interfaces within the piezoelectric layer that could generate energy losses.

The piezoelectric layer can be made of lithium niobate (LiNbO₃), lithium tantalate (LiTaO₃), potassium niobate (KNbO₃), potassium and sodium niobate (KNaNbO₃), lead zirconate titanate (PbZrTiO₃), quartz (SiO₂), aluminum nitride (AlN), aluminum-scandium nitride (AlScN) and zinc oxide (ZnO). In particular, in the case of power converters, the piezoelectric layer is made of lithium niobate (LiNbO₃), lithium tantalate (LiTaO₃), potassium niobate (KNbO₃), potassium and sodium niobate (KNaNbO₃), lead titanate-zirconate (PbZrTiO₃) or quartz (SiO₂).

The thickness of the piezoelectric layer can be constant to the nearest 1%, preferably to the nearest 0.1%, at least in the resonator area, preferably in all the areas.

The thickness of the piezoelectric layer can be greater than or equal to 10 μm, preferably greater than or equal to 25 μm, more preferably greater than or equal to 50 μm. Such thicknesses are particularly advantageous for power converter applications.

### Electrodes

The electrodes can have the same thickness to the nearest 20%, preferably to the nearest 10%, more preferably to the nearest 5%.

The electrodes can each have a constant thickness to the nearest 1%, preferably to the nearest 0.1%, over their entire extension.

The electrodes can have a circular, oval or polygonal contour, notably a square contour. The invention is not limited to a particular shape for the electrodes.

The thickness of the electrodes can be less than the thickness of the piezoelectric layer, notably less than one third, more preferably less than one fifth, of the thickness of the piezoelectric layer.

### Frames

Preferably, the frames are each in contact with the corresponding electrode over at least a portion of the periphery of the electrode. They can be arranged laterally on the corresponding electrode on the edge thereof or at a distance from the edge that is less than or equal to 5%, preferably 2%, of the thickness of the piezoelectric layer, or they can laterally border the corresponding electrode over its entire perimeter, being in lateral contact therewith over at least a portion of its perimeter. Each impedance discontinuity completes a surface with a different dimension, and each dimension allows additional resonant modes to exist. Furthermore, each impedance discontinuity facilitates the transposition of one deformation mode to another deformation mode and thus the transfer of energy from one mode to another. Thus, the presence of a space between the electrode and the frame increases the number of possible resonant modes and facilitates the transfer of energy from the desired main mode to the other unwanted modes. Thus, the lack of space between the electrode and the frame allows an additional mechanical impedance discontinuity to be avoided that would be associated with an intermediate space. By thus limiting the impedance discontinuities, the risks of transferring energy to unwanted resonant modes is reduced.

The frames can delimit the electrodes over more than 80%, preferably more than 90%, more preferably more than 95% of their periphery, notably entirely.

When using piezoelectric materials that are not isotropic in the plane, such as lithium niobate (LiNbO₃) or lithium tantalate (LiTaO₃), it is worthwhile adapting the width of the frame according to the orientation of each elementary portion of the frame relative to the crystalline orientation of the material. Typically, the width of the frame can be non-constant and can depend, at each location on the frame, on the difference between the direction normal to this frame in the plane of the material and the crystalline direction of the material defined in the same three-dimensional coordinate system attached to the plane of the material.

Preferably, the thickness of the frames is substantially constant.

The width and the thickness of the frames are preferably selected so that substantially a quarter wave propagates over the width of the frames at a predetermined working frequency of the resonator. This promotes the piston mode in the work area and promotes substantially synchronous deformation and substantially homogeneous amplitude in the work area.

The width of the frames can range between 5 μm and 2,000 μm, preferably between 50 μm and 1,500 μm, more preferably between 50 μm and 300 μm in the case of a power converter in particular.

Notably, the width of the frames is less than or equal to four times the thickness of the piezoelectric layer, preferably less than or equal to three times the thickness of the piezoelectric layer, more preferably less than or equal to half the thickness of the piezoelectric layer.

Advantageously, the width of the frames can be defined to the nearest 30%, preferably to the nearest 15%, more preferably to the nearest 5%, according to the following formula:

$${k}_{f r a m e} tan ( {k}_{f r a m e} W ) = j {k}_{e x t}$$

where W represents the width of the frames and k_{frame} and kₑₓₜ respectively represent the wave numbers of the frame area and of the external area at a predetermined working frequency of the resonator for predetermined thicknesses of the piezoelectric layer and of the frames. This feature notably allows optimal precision to be provided for dimensioning the resonator frames, which particularly minimizes the energy losses and the parasitic resonant modes. Defining the width of the frames with precision of 30%, 15%, or even 5%, ensures that the frames are dimensioned so as to maximize the efficiency of the electromechanical coupling and to confine the acoustic waves inside the resonator. This also reduces the risk of deformation and distortion, thereby improving the stability and the overall performance of the resonator.

The predetermined working frequency of the resonator can range between the resonant frequency and the anti-resonant frequency of the work area, and notably can be substantially the geometric center between the resonant frequency and the weighted or unweighted anti-resonant frequency.

The frames can be thicker than the electrodes. The cumulative over-thickness of the two frames can be greater than or equal to 1 μm, preferably greater than or equal to 10 μm.

As a variant, the frames can be thinner than the electrodes. The cumulative under-thickness of the two frames can be greater than or equal to 1 μm, preferably greater than or equal to 10 μm.

In one embodiment, the frames are made of an electrically insulating material, notably silicon oxide or silicon nitride.

In the case whereby the frames are made of an electrically insulating material and whereby the frames are thicker than the electrodes, the thickness of the frames can be defined so that, for a zero wave number, the resonant frequency of the frame area is lower than the resonant frequency of the work area, notably at least 3%, preferably at least 6%, lower than the resonant frequency of the work area. Furthermore, at the same time, in this case, the resonant frequency of the external area must be greater than the anti-resonant frequency of the work area, notably at least 3% greater, preferably at least 6% greater.

In the case whereby the frames are made of an electrically insulating material and whereby the frames are thinner than the electrodes, the thickness of the frames can be defined so that, for a zero wave number, the resonant frequency of the frame area is greater than the anti-resonant frequency of the work area, notably at least 3%, preferably at least 6%, greater than the anti-resonant frequency of the work area.

In the case whereby the frames are made of an electrically insulating material, the thickness of the frames is preferably defined so that, for a zero wave number, the resonant frequency of the frame area is lower than the resonant frequency of the external area.

In another embodiment, the frames can be made of an electrically conductive material, notably the material of the frames can be the same as the material of the corresponding electrode. They can be made of a metal, notably copper, nickel, aluminum, molybdenum, tungsten, ruthenium, platinum or gold. This notably facilitates manufacturing and limits the presence of an interface that could result in an energy loss, for example, resistive losses.

In the case whereby the frames are made of an electrically conductive material and whereby the frames are thicker than the electrodes, the thickness of the frames can be defined so that, for a zero wave number, the resonant frequency of the frame area is lower than the resonant frequency of the resonator area, notably at least 3%, preferably at least 6%, lower than the resonant frequency of the resonator area.

In the case whereby the frames are made of an electrically conductive material and whereby the frames are thinner than the electrodes, the thickness of the frames can be defined so that, for a zero wave number, the anti-resonant frequency of the frame area is greater than the anti-resonant frequency of the resonator area, notably at least 3%, preferably at least 6%, greater than the anti-resonant frequency of the resonator area.

In the case whereby the frames are made of an electrically conductive material, the thickness of the frames can be defined so that, for a zero wave number, the anti-resonant frequency of the frame area is lower than the resonant frequency of the external area.

### External Area

Preferably, the resonator is devoid of electrodes outside the areas delimited by the frames on either side of the piezoelectric layer.

The thickness of the piezoelectric layer can be reduced in the external area relative to its thickness in the frame area and in the resonator area.

Preferably, the external area is configured so that, for a zero wave number, its resonant frequency is greater than the anti-resonant frequency of the work area, notably at least 3%, preferably at least 6%, more preferably at least 18%, greater than the anti-resonant frequency of the resonator area.

### Electrical Connection

Preferably, the resonator comprises electrical contacts for connecting each of the electrodes to an electrical circuit, notably each in contact with an electrode and/or a frame. The electrical contacts on either side of the piezoelectric layer preferably are not superposing. This prevents any vibration of the piezoelectric layer from occurring between these contacts in the external area. In the case of frames with an over-thickness and which are made of a conductive material, the electrical contacts can be integrated into the frames and can have a thickness that is substantially equal to the over-thickness of the frames. In the case of frames with an over-thickness and which are made of an insulating material, the electrical contacts can be integrated into the corresponding frame either by interrupting the frame locally, or by superposing the frame locally, passing above or below said frame.

### Dual Frame

The resonator can comprise additional frames on either side of the piezoelectric layer in the external area. The additional frames can be substantially symmetrical with respect to each other relative to the median plane extending through the middle of the thickness of the piezoelectric layer. The additional frames can have different widths and/or thicknesses from the frames.

The invention also at least partly addresses this requirement by means of a power converter comprising the piezoelectric resonator as described above.

### Method for Using the Resonator

The invention also addresses the aforementioned requirement by means of a method for using the resonator as described above as a power converter.

The operating frequency range of the converter can range between the resonant frequency and the anti-resonant frequency of the work area defined by the superposing area of the piezoelectric layer and of the electrodes, with the resonant frequency and the anti-resonant frequency being defined for a zero wave number.

### BRIEF DESCRIPTION OF THE DRAWINGS

FIG. 1 schematically shows a cross-section of an example of a piezoelectric resonator;

FIG. 2 schematically shows a cross-section of a variant of a piezoelectric resonator;

FIG. 3 schematically shows a cross-section of a variant of a piezoelectric resonator;

FIG. 4 schematically shows a cross-section of a variant of a piezoelectric resonator;

FIG. 5 schematically shows a cross-section of a variant of a piezoelectric resonator;

FIG. 6 shows dispersion curves in the various areas of an example of a piezoelectric resonator;

FIG. 7 schematically shows a cross-section of a variant of a piezoelectric resonator; and

FIG. 8 schematically shows a top view of a variant of a piezoelectric resonator.

### DETAILED DESCRIPTION

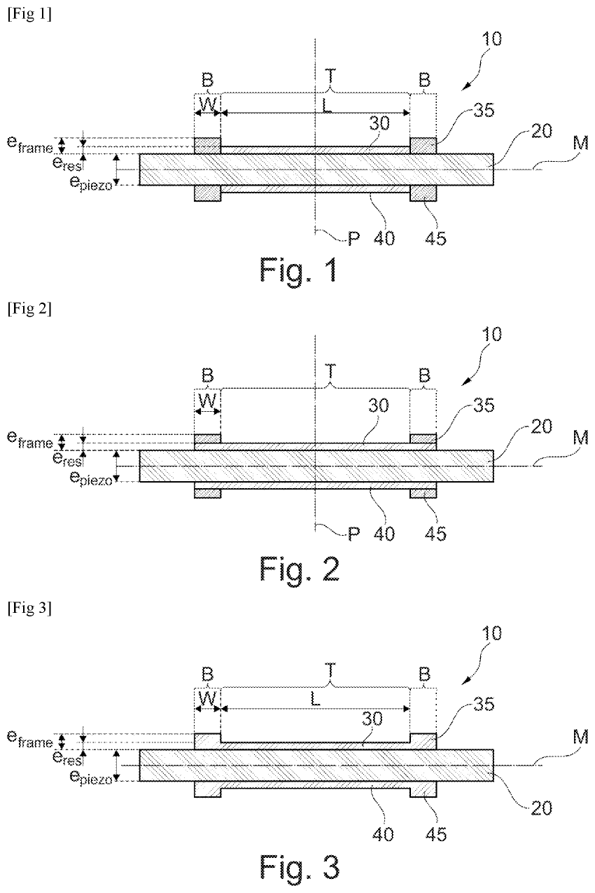

FIG. 1 illustrates a piezoelectric resonator 10 comprising a piezoelectric layer 20 sandwiched between two conductive electrodes 30 and 40. The two electrodes 30 and 40 are laterally delimited by frames 35 and 45, respectively, which have different thicknesses from the electrodes 30 and 40. The frames 35 and 45 on either side of the piezoelectric layer 20 are substantially symmetrical with respect to a median plane M of the piezoelectric layer 20. In this case, they are shown as perfectly symmetrical with respect to the median plane M, but there is obviously a tolerance in the symmetry that nevertheless has an advantageous effect on the resonator 10. The frames can be identical to the nearest 20%, preferably to the nearest 10%, preferably to the nearest 5%, and they can be positioned at their mutual reference point to the nearest 20%, preferably to the nearest 10%, more preferably to the nearest 5%.

The area T defined by superposing the piezoelectric layer 20 and the electrodes 30 and 40 (excluding the frames) forms the work area where the waves are to be confined and where synchronous deformation and homogeneous amplitude is sought. The one or more areas B defined by superposing the piezoelectric layer 20 and the frames 35 and 45 form the one or more frame areas allowing controlled transition of the deformation between the external area and the work area T in order to address the requirements of the invention.

In the illustrated example, the piezoelectric layer 20 is a single layer made of a single material over its entire surface area, which notably avoids any internal interfaces that could generate energy losses. However, this could be otherwise. Notably, it could be a multilayer made of the same or of different piezoelectric materials. In the case of a multilayer, it is devoid of electrodes in the multilayer structure and the layers are preferably in contact with each other.

The piezoelectric layer 20 can be made of lithium niobate (LiNbO₃), lithium tantalate (LiTaO₃), potassium niobate (KNbO₃), potassium and sodium niobate (KNaNbO₃), lead zirconate titanate (PbZrTiO₃), quartz (SiO₂), aluminum nitride (AlN), aluminum-scandium nitride (AlScN) or zinc oxide (ZnO). Preferably, in the case of power converters, the piezoelectric layer 20 is made of lithium niobate (LiNbO₃), lithium tantalate (LiTaO₃), potassium niobate (KNbO₃), potassium and sodium niobate (KNaNbO₃), lead titanate-zirconate (PbZrTiO₃) or quartz (SiO₂). The thickness e_{piezo} of the piezoelectric layer 20 is constant to the nearest 1%, preferably to the nearest 0.1%, at least in the work area T, preferably over its entire extent.

Each conductive electrode 30 or 40 can have a constant thickness eᵣₑₛ to the nearest 1%, preferably to the nearest 0.1%, over its entire extent. In the illustrated example, the thickness eᵣₑₛ is less than one fifth of the thickness e_{piezo} of the piezoelectric layer 20. The electrodes 30 and 40 can have a circular, oval or polygonal contour, notably a square contour.

In the illustrated example, the electrodes 30 and 40 are substantially identical and symmetrical with respect to the median plane M. Of course, as for the frames, there is a tolerance. The electrodes can be identical to the nearest 20%, preferably to the nearest 10%, more preferably to the nearest 5%, and they can be positioned relative to each other to the nearest 20%, preferably to the nearest 10%, more preferably to the nearest 5%.

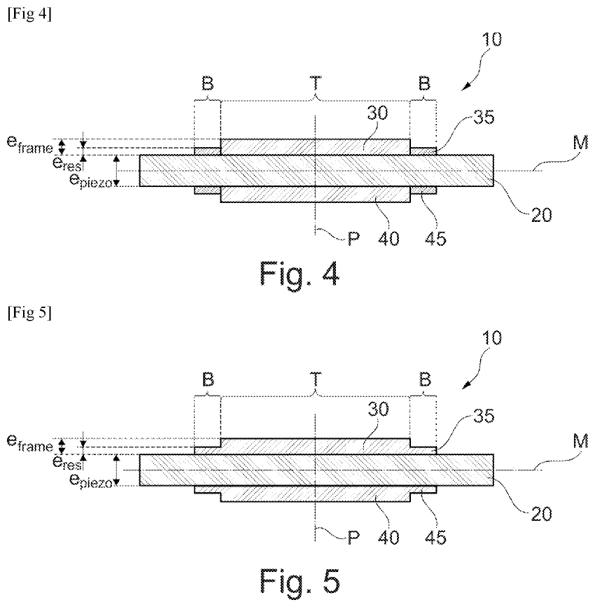

The thicknesses e_{frame} of the frames 35 and 45 differ from the thickness eᵣₑₛ of the electrodes 30 and 40. This thickness e_{frame} of the frames can be greater than the thickness eᵣₑₛ of the electrodes 30 and 40, as illustrated in FIGS. 1 to 3, or can be less than the thickness eᵣₑₛ of the electrodes 30 or 40, as illustrated in FIGS. 4 and 5.

The frames 35 and 45 preferably are each in contact with the corresponding electrode 30 or 40 over at least a portion of the periphery of the electrode 30 or 40. The frames 35 and 45 can delimit the electrodes 30 and 40 over more than 80%, preferably more than 90%, even more preferably more than 95%, of their periphery, preferably entirely.

They can laterally border the corresponding electrode 30 or 40 over its entire perimeter, being in lateral contact therewith over at least a portion of its perimeter, as illustrated in FIGS. 1 and 4. As a variant, illustrated in FIG. 2, they advantageously can be arranged laterally on the corresponding electrode on the edge thereof or otherwise in the immediate vicinity of the edge, notably at a distance from the edge that is less than 5%, preferably 2%, of the thickness of the piezoelectric material.

The resonator 10 preferably is devoid of an electrode 30 or 40 outside the areas delimited by the frames 35 and 45 on either side of the piezoelectric layer 20. The thickness e_{piezo} of the piezoelectric layer 20 can be reduced in the external area relative to its thickness in the frame area B and in the work area T.

The electrodes 30 and 40 are preferably made of the same conductive material, notably copper, nickel, aluminum, molybdenum, tungsten, ruthenium, platinum or gold. Preferably, the electrodes and the frames are substantially symmetrical with respect to the median plane M and to a plane transverse to the median plane P. The entire resonator can exhibit such symmetries with respect to the median plane M and to a transverse plane P.

In the case of piezoelectric materials that are not isotropic in the plane, such as lithium niobate (LiNbO₃) or lithium tantalate (LiTaO₃), it is worthwhile adapting the width W of the frames 35 and 45 according to the orientation of each elementary portion of the frame relative to the crystalline orientation of the material.

The frames 35 and 45 preferably have a substantially constant thickness e_{frame} across the entire frame.

The frames 35 and 45 can be made of the same material as the corresponding electrode, as illustrated in FIGS. 3 and 5. This notably facilitates manufacturing and limits the presence of an interface that could result in an energy loss. As a variant, illustrated in FIGS. 1, 2 and 4, they can be made of a different material. In this latter case, they can be made of a conductive or insulating material.

The width W and the thickness e_{frame} of the frames 35 and 45 are preferably selected so that a fraction of a wave substantially corresponding to a quarter wave propagates over the width of the frames at a predetermined working frequency f_{work} of the resonator. This promotes the piston mode in the work area T and promotes substantially synchronous deformation and substantially homogeneous amplitude in the work area T.

The thickness e_{frame} of the frames 35 and 45 can be selected to provide a good compromise between reduced manufacturing costs/constraints, which are notably greater for thicker frames, and the least possible number of unwanted modes excited at the working frequency f_{work}. The thickness e_{frame} of the frames 35 and 45 can be substantially independent of the width L of the electrodes 30 and 40.

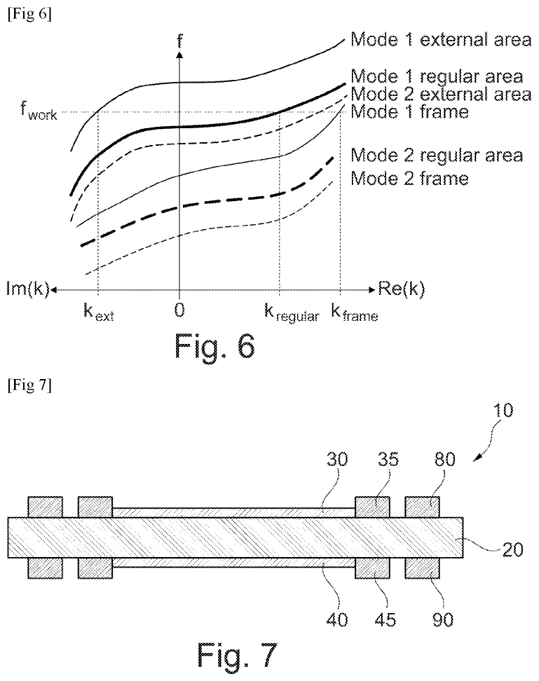

Advantageously, the width W of the frames 35 and 45 can be defined to the nearest 30%, preferably to the nearest 15%, more preferably to the nearest 5%, according to the following formula:

$${k}_{f r a m e} tan ( {k}_{f r a m e} W ) = j {k}_{e x t}$$

where k_{frame} and kₑₓₜ respectively are the wave number of the frame area B and the wave number of the external area at a predetermined working frequency of the resonator 10 for predetermined thicknesses of the piezoelectric layer e_{piezo} and of the frames e_{frame}. The wave numbers can be determined from predetermined dispersion curves, as illustrated in FIG. 6, notably by periodic finite element simulation, notably using Bloch-Floquet conditions imposing a phase relationship between the two edges of the mesh at the working frequency for the various areas. These dispersion curves can be determined for different modes (in this case modes 1 and 2) for the work area (regular area), the frame area (frame) and the external area (external area). Determining the other modes also ensures that the transfer to the other parasitic modes, notably mode 2 in this case, remains negligible. This feature notably allows an optimum to be approximated in terms of the dimensioning of the resonator frames, which particular allows the energy losses and the parasitic resonant modes to be minimized. Advantageously, defining the width of the frames with precision of 30%, 15% or even 5%, ensures that the frames are dimensioned so as to maximize the efficiency of the electromechanical coupling and to confine the acoustic waves inside the resonator. This also reduces the risks of deformation and distortion, thereby improving the stability and the overall performance of the resonator. The frame width can be between 5 μm and 2 mm.

As a variant, for a predetermined frame thickness e_{frame} for the frames 35 and 45, the width W of the frame according to the working frequency f_{work} can be determined from a pre-established curve of the width W determined according to the previous equation according to the working frequency f_{work}. It is then possible to refer only to charts of the optimum width according to the frequency for various frame thicknesses. Thus, after determining the optimal thickness e_{frame}, it is possible to easily determine the optimal width W at the working frequency f_{work} or the optimal width range within the working frequency range, notably between the resonant frequency f_{res_s} and the anti-resonant frequency f_{res_p} of the work area T.

The working frequency of the resonator f_{work} can range between the resonant frequency f_{res_s} and the anti-resonant frequency f_{res_p} of the work area, and notably substantially can be the geometric center between the resonant frequency f_{res_r} and the weighted or unweighted anti-resonant frequency f_{res_p}.

Preferably, the width W of the frames 35 and 45 is less than or equal to four times the thickness of the piezoelectric layer e_{piezo}, preferably less than or equal to three times the thickness of the piezoelectric layer e_{piezo}, more preferably less than or equal to half the thickness of the piezoelectric layer e_{piezo}.

In the case whereby the frames 35 and 45 are made of an electrically insulating material and the frames 35 and 45 are thicker than the electrodes 30 and 40, as illustrated in FIGS. 1 to 3, the thickness e_{frame} of these frames is defined so that, for a zero wave number, the resonant frequency f_{frame} of the frame area B is lower than the resonant frequency fₑₓₜ of the external area. The thickness e_{frame} of the frames also can be defined so that, for a zero wave number, the resonant frequency f_{frame} of the frame area B is lower than the resonant frequency f_{res_s} of the work area T, notably at least 3%, preferably at least 6%, lower than the resonant frequency f_{res_s} of the work area T. If they are thinner than the electrodes 30 and 40, as illustrated in FIGS. 4 and 5, the thickness of the frames e_{frame} can be defined so that, for a zero wave number, the resonant frequency of the frame area f_{frame} is greater than the anti-resonant frequency of the work area f_{res_p}, notably is at least 3%, preferably at least 6%, greater than the anti-resonant frequency of the work area f_{res_p}.

In the case whereby the frames 35 and 45 are made of an electrically conductive material and the frames 35 and 45 are thicker than the electrodes 30 and 40, as illustrated in FIGS. 1 to 3, the thickness e_{frame} of the frames is preferably defined so that, for a zero wave number, the resonant frequency f_{frame_s} of the frame area B is lower than the resonant frequency of the resonator area f_{res_s}, notably is at least 3%, preferably at least 6%, lower than the resonant frequency of the resonator area f_{res_s}. If they are thinner than the electrodes 30 and 40, the thickness of the frames e_{frame} can be defined so that, for a zero wave number, the anti-resonant frequency of the frame area f_{frame_p} is greater than the anti-resonant frequency of the work area f_{res_p}, notably is at least 3%, preferably at least 6%, greater than the anti-resonant frequency of the work area f_{res_p}.

In both these cases, the external area is preferably configured so that, for a zero wave number, its resonant frequency fₑₓₜ is greater than the anti-resonant frequency of the work area f_{res_p}, notably is at least 3%, preferably at least 6%, more preferably at least 18%, greater than the anti-resonant frequency of the work area f_{res_p}.

The dimensions also depend on the working frequency f_{work} and therefore on the application. Typically, for a power converter, the thickness e_{piezo} of the piezoelectric layer 20 is greater than or equal to 50 μm, the thickness eᵣₑₛ of the electrodes is greater than or equal to 1 μm, for example, of the order of tens of micrometers, and the thickness and the frames 35 and 45 can have an over-thickness or an under-thickness e_{frame} of the order of a few micrometers and a width W ranging between 5 μm and 2,000 μm, preferably between 50 μm and 1,500 μm, more preferably between 50 μm and 300 μm.

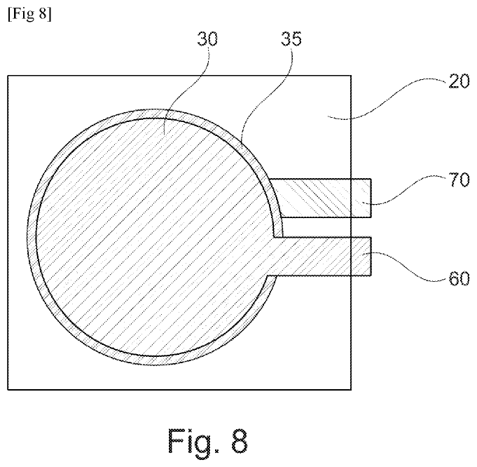

The resonator 10 further comprises electrical contacts 60 and 70 for connecting each of the electrodes to an electrical circuit, notably each in contact with one of the electrodes 30 and 40 and/or a frame 35 and 45. The electrical contacts 60 and 70 on either side of the piezoelectric layer 20 preferably are not superposing. This prevents any vibration of the piezoelectric layer 20 from occurring between these contacts 60 and 70 in the external area. Such electrical contacts 60 and 70 are shown in FIG. 8.

In the case of frames 35 and 45 with an over-thickness and that are made of a conductive material, the electrical contacts 60 and 70 can be integrated into the frames 35 and 45 and have a thickness that is substantially equal to the over-thickness of the frames. In the case of frames with an over-thickness and that are made of an insulating material, the electrical contacts can be integrated into the corresponding frame either by interrupting the frame locally or by superposing them on the frame locally, passing above or below said frame.

The embodiment illustrated in FIG. 7 differs from that of FIG. 1 in that the resonator 10 can comprise additional frames 80 and 90 on either side of the piezoelectric layer 20 in the external area. The additional frames 80 and 90 can be substantially symmetrical with respect to each other relative to the median plane M. The additional frames 80 and 90 can have the same width and thickness as the frames 35 and 45. As a variant, they can have a different width and/or thickness from the frames 35 and 45.

### Example of Dimensioning

In an example of an implementation according to the invention illustrated in FIG. 1 for a power converter, the piezoelectric layer is 500 μm thick and made of LNO (lithium niobate) with a crystal orientation of Y36° relative to the electrodes, the electrodes 30 and 40 have a circular contour and are 15 μm thick. They are bounded by frames 35 and 45 that are 30 μm thick and 1.2 mm wide, joined to the electrodes. This resonator is used over a working range of around 6 MHz. The resonator is perfectly symmetrical with respect to a median plane of the piezoelectric layer and with respect to a median plane perpendicular to this median plane.

The invention is not limited to the embodiments described above. The features can be combined when this is technically possible. Furthermore, as stated, there is a tolerance in the dimensions and/or the mutual positioning of the elements, allowing advantageous, if not equivalent, performance capabilities to be provided.

1. A piezoelectric resonator comprising:
a piezoelectric layer;
two conductive electrodes extending on either side of the piezoelectric layer so that the piezoelectric layer is sandwiched between the two conductive electrodes, with each conductive electrode being laterally delimited by a frame having a thickness different from that of the corresponding electrode;
the frames of the two electrodes being substantially symmetrical with respect to each other relative to a median plane M extending through the middle of the thickness e_{piezo} of the piezoelectric layer.

2. The resonator as claimed in claim 1, comprising:
a work area T defined by the superposing area of the piezoelectric layer and of the electrodes;
a frame area B defined by the superposing area of the piezoelectric layer and of the frames and having a thickness different from that of the work area T; and
an external area defined outside the other two areas B and T.

3. The resonator as claimed in claim 2, wherein the thickness e_{piezo} of the external area is less than that of the work area T and of the frame area B.

4. The resonator as claimed in claim 1, wherein the resonator is substantially symmetrical relative to the median plane M extending through the middle of the thickness e_{piezo} of the piezoelectric layer.

5. The resonator as claimed in claim 1, wherein the thickness e_{piezo} of the piezoelectric layer and the thickness eᵣₑₛ of the electrodes is constant to the nearest at least 1% in the resonator area, preferably in all the areas.

6. The resonator as claimed in claim 1, wherein the frames are each in contact with the corresponding electrode over at least a portion of the periphery of the electrode.

7. The resonator as claimed in claim 1, wherein the thickness e_{piezo} of the piezoelectric layer is greater than or equal to 10 μm and the width W of the frames is less than or equal to four times the thickness e_{piezo} of the piezoelectric layer.

8. The resonator as claimed in claim 1, wherein the width W and the thickness e_{frame} of the frames are selected so that a quarter wave propagates in the width W of the frames at a predetermined working frequency f_{work} of the resonator.

9. The resonator as claimed in claim 1, wherein the width W of the frames is defined to the nearest 30%, preferably to the nearest 15%, more preferably to the nearest 5%, according to the following formula:
$${k}_{f r a m e} tan ( {k}_{f r a m e} W ) = j {k}_{e x t}$$
where W represents the width of the frames and k_{frame} and kₑₓₜ respectively represent the wave numbers of the frame area B and of the external area at a predetermined working frequency f_{work} of the resonator for predetermined thicknesses of the piezoelectric layer and of the frames.

10. The resonator as claimed in claim 8, wherein the predetermined working frequency f_{work} of the resonator ranges between the resonant frequency f_{res_s} and the anti-resonant frequency f_{res_p} of the work area T.

11. The resonator as claimed in claim 8, wherein the predetermined working frequency f_{work} of the resonator is substantially the geometric center between the resonant frequency f_{res_s} and the weighted or unweighted anti-resonant frequency f_{res_p}.

12. The resonator as claimed in claim 1, wherein the frames are made of an electrically insulating material.

13. The resonator as claimed in claim 12, wherein the thickness e_{frame} of the frames is defined so that, for a zero wave number, the resonant frequency f_{frame} of the frame area is lower than the resonant frequency fₑₓₜ of the external area.

14. The resonator as claimed in claim 12, wherein the frames are thicker than the electrodes and the thickness e_{frame} of the frames is defined so that, for a zero wave number, the resonant frequency f_{frame} of the frame area is lower than the resonant frequency f_{res_s} of the work area.

15. The resonator as claimed in claim 12, wherein the frames are thinner than the electrodes and the thickness e_{frame} of the frames is defined so that, for a zero wave number, the resonant frequency f_{frame} of the frame area is greater than the anti-resonant frequency f_{res_p} of the work area.

16. The resonator as claimed in claim 1, wherein the frames are made of an electrically conductive material, notably the material of the frames can be the same as the material of the corresponding electrode.

17. The resonator as claimed in claim 16, wherein the thickness e_{frame} of the frames is defined so that, for a zero wave number, the anti-resonant frequency f_{frame_s} of the frame area is lower than the resonant frequency fₑₓₜ of the external area.

18. The resonator as claimed in claim 16, wherein the frames are thicker than the electrodes and the thickness e_{frame} of the frames is defined so that, for a zero wave number, the resonant frequency f_{frame_s} of the frame area is lower than the resonant frequency f_{res_s} of the resonator area.

19. The resonator as claimed in claim 16, wherein the frames are thinner than the electrodes and the thickness of the frames is defined so that, for a zero wave number, the anti-resonant frequency f_{frame_p} of the frame area is greater than the anti-resonant frequency f_{res_p} of the resonator area.

20. The resonator as claimed in claim 1, comprising electrical contacts for connecting each of the electrodes to an electrical circuit, with the electrical contacts on either side of the piezoelectric layer not superposing each other.

21. The resonator as claimed in claim 1, comprising additional frames on either side of the piezoelectric layer in the external area, which are substantially symmetrical with respect to each other relative to the median plane M extending through the middle of the thickness of the piezoelectric layer.

22. A power converter comprising a piezoelectric resonator as claimed in claim 1.

23. A method for using the piezoelectric resonator as claimed in claim 1 in a power converter.
